(19) United States
(12) Patent Application Publication
(10) Pub. No.: US 2010/0043708 A1
(43) Pub. Date: Feb. 25, 2010

(54) CERAMIC HEATER, METHOD OF MANUFACTURING THE SAME, AND APPARATUS FOR FORMING A THIN LAYER HAVING THE SAME

(76) Inventors: Jeong-Duck CHOI, Seoul (KR); Seong-Min LEE, Seoul (KR); Jin-Sik CHOI, Seoul (KR)

Correspondence Address: DALY, CROWLEY, MOFFORD & DURKEE, LLP, SUITE 301A, 354A TURNPIKE STREET, CANTON, MA, 02021-2714, US

(21) Appl. No.: 12/543,100

(22) Filed: Aug. 18, 2009

(30) Foreign Application Priority Data
Aug. 20, 2008 (KR) 10-2008-0081158

(51) Int. Cl. C23C 16/50; H05B 3/68; H01C 17/02; H05B 3/18

(52) U.S. Cl. 118/723 E; 219/444.1; 29/611; 219/544; 219/553

(57) ABSTRACT

A ceramic heater capable of reducing power consumption, a method of manufacturing the ceramic heater and an apparatus for forming a thin layer having the ceramic heater are disclosed. The ceramic heater includes a plate, a first heating layer, a second heating layer and a connecting member. The first and second heater layers are disposed parallel to each other within the plate. The connecting member includes a ceramic material having a negative temperature coefficient (NTC) to electrically connect the first heating layer with the second heating layer at a temperature higher than a predetermined target temperature.

### CROSS-REFERENCE TO RELATED APPLICATIONS

This application claims priority under 35 U.S.C. §119 to Korean Patent Application No. 2008-81158, filed on Aug. 20, 2008 in the Korean Intellectual Property Office (KIPO), the contents of which are herein incorporated by reference in their entirety.

### BACKGROUND

1. Field

The example embodiments relate generally to a ceramic heater, a method of manufacturing the ceramic heater and an apparatus for forming a thin layer having the ceramic heater. More particularly, the example embodiments relate to a ceramic heater for heating a substrate to form a thin layer on the substrate, a method of manufacturing the ceramic heater and an apparatus for forming a thin layer having the ceramic heater.

2. Description of the Related Art

Generally, semiconductor devices are generally manufactured through a series of unit processes such as a fabricating process, an electrical die sorting (EDS) process and a packaging process. Various electric circuits and devices are fabricated on a semiconductor substrate such as a silicon wafer in the fabricating process, and electrical characteristics of the electric circuits are inspected and defective chips are detected in the wafer in the EDS process. Then, the devices are individually separated from the wafer and each device is sealed in an epoxy resin and packaged into an individual semiconductor device in the packaging process.

The fabricating process may include a process for a thin layer on the substrate, a process for forming a photoresist pattern on the thin layer, a process for etching the thin layer using the photoresist pattern, a process for removing the photoresist pattern, and the like.

The thin layer may be formed by performing a chemical vapor deposition (CVD) process, a physical vapor deposition (PVD) process, and the like. Recently, a plasma-enhanced chemical vapor deposition (PECVD) process may be generally employed, which may form a thin layer using a plasma.

An apparatus for performing the PECVD process may include a process chamber into which a reactive gas is supplied, a plasma electrode disposed in the process chamber to form a plasma from the reactive gas to thereby form the thin layer on the substrate, and a supporter on which the substrate is placed. Here, a ceramic heater may be used as the supporter to heat the substrate to a desired process temperature.

The ceramic heater includes a plate made of an insulating ceramic material, which the substrate is placed on an upper surface thereof, and first and second heating layers disposed within the plate to generate heat. The first and second heating layers are directly connected with an external power supply, and driving power is applied to the first and second heating layers from the power supply at the same time.

That is, the driving power is applied to both of the first and second heating layers early in the heat generation using the first and second heating layers, and the power consumption of the ceramic heater may thus be increased.

### SUMMARY

Example embodiments of the present invention provide a ceramic heater capable of reducing power consumption.

Further, example embodiments of the present invention provide a method of manufacturing the ceramic heater.

Still further, example embodiments of the present invention provide an apparatus for forming a thin layer including the ceramic heater.

In accordance with an aspect of the present invention, a ceramic heater may include a plate including a ceramic material and supporting a substrate, a first heating layer disposed within the plate, a second heating layer disposed parallel to the first heating layer within the plate and connected with a power supply for providing driving power, and a connecting member disposed between the first heating layer and the second heating layer to electrically connect the first heating layer with the second heating layer at a temperature higher than a predetermined target temperature.

In accordance with some example embodiments of the present invention, the connecting member may include a ceramic material having a negative temperature coefficient (NTC).

In accordance with some example embodiments of the present invention, the connecting member may include a first metal oxide and a second metal oxide. Examples of a first metal that may be used for the first metal oxide may include aluminum (Al), magnesium (Mg), and the like. Examples of a second metal that may be used for the second metal oxide may include indium (In), tin (Sn), manganese (Mn), cobalt (Co), nickel (Ni), chromium (Cr), copper (Cu), and the like. These second metals may be used alone or in a combination thereof. For example, indium-tin (In—Sn) may be used as the second metal.

In accordance with some example embodiments of the present invention, the connecting member may include at least two of metal oxides such as barium oxide (BaO), titanium oxide (TiO₂), lead oxide (PbO), zirconium oxide (ZrO₂), yttrium oxide (Y₂O₃), and the like.

In accordance with some example embodiments of the present invention, the target temperature may be about 0.4 to about 0.6 times a process temperature for processing the substrate.

In accordance with some example embodiments of the present invention, the first heating layer may correspond to a portion of the second heating layer.

In accordance with some example embodiments of the present invention, each of the first and second heating layers may be a heating wire having a plate-like structure.

In accordance with some example embodiments of the present invention, a portion of the plate between the first and second heating layers may include about 0.01 to about 1.0 percent by weight of at least one of magnesium oxide (MgO) and titanium oxide (TiO₂).

In accordance with some example embodiments of the present invention, the ceramic heater may further include a supporter for supporting the plate. Here, the second heating layer may be connected to the power supply by a power line passing through the supporter.

In a method of manufacturing a ceramic heater, in accordance with another aspect of the present invention, a first ceramic powder may be supplied in a mold space to form a first ceramic layer. A first heating layer may be disposed on the first ceramic layer, and a connecting member, which may have electrical conductivity at a temperature higher than a predetermined target temperature, may be connected with the first heating layer. A second ceramic powder may be supplied onto the first ceramic layer to form a second ceramic layer. Here, an upper portion of the connecting member may be exposed. A second heating layer may be disposed on the second ceramic layer so that the second heating layer may be connected with the exposed upper portion of the connecting member.

In accordance with some example embodiments of the present invention, a third ceramic powder may be supplied onto the second ceramic layer to form a third ceramic layer, and the first, second and third ceramic layers supplied in the mold space may be formed in one piece by a sintering process.

In accordance with some example embodiments of the present invention, the first, second and third ceramic powders may include aluminum nitride (AlN). Particularly, the second ceramic powder may further include at least one of magnesium oxide (MgO) and titanium oxide (TiO₂). For example, the second ceramic powder may further include about 0.01 to about 1.0 percent by weight of magnesium oxide (MgO), titanium oxide (TiO₂) or a mixture of magnesium oxide (MgO) and titanium oxide (TiO₂).

In accordance with still another aspect of the present invention, an apparatus for forming a thin layer may include a process chamber, a ceramic heater disposed in the process chamber to support a substrate and to heat the substrate to a process temperature, and a plasma electrode disposed opposite to the ceramic heater in the process chamber to form a plasma from a reactive gas supplied into the process chamber so as to form the thin layer on the substrate. Here, the ceramic heater may include a plate comprising a ceramic material and supporting the substrate, a first heating layer disposed within the plate, a second heating layer disposed parallel to the first heating layer within the plate and connected with a power supply for providing driving power, and a connecting member disposed between the first heating layer and the second heating layer to electrically connect the first heating layer with the second heating layer at a temperature higher than a predetermined target temperature.

In accordance with some example embodiments of the present invention, the target temperature may be about 0.4 to about 0.6 times the process temperature, and the connecting member may include a ceramic material having an NTC.

In accordance with the example embodiments of the present invention as described above, a ceramic heater may be heated by a second heating layer at a temperature lower than a target temperature and may be heated by both of the first and second heating layers at a temperature higher than the target temperature. Thus, power consumption may be reduced early in the heat generation of the ceramic heater.

### BRIEF DESCRIPTION OF THE DRAWINGS

Example embodiments of the present invention will become readily apparent along with the following detailed description when considered in conjunction with the accompanying drawings, in which:

FIG. 1 is a schematic view illustrating a ceramic heater in accordance with an example embodiment of the present invention;

FIG. 2 is a graph illustrating the temperature and electrical resistance of a connecting member of the ceramic heater shown in FIG. 1;

FIGS. 3A to 3E are schematic views illustrating a method of manufacturing the ceramic heater shown in FIG. 1; and

FIG. 4 is a schematic view illustrating an apparatus for forming a thin layer including the ceramic heater shown in FIG. 1.

### DESCRIPTION OF THE EMBODIMENTS

The present invention is described more fully hereinafter with reference to the accompanying drawings, in which example embodiments of the present invention are shown. The present invention may, however, be embodied in many different forms and should not be construed as limited to the example embodiments set forth herein. Rather, these embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on” or “connected to” another element or layer, it can be directly on or connected to the other element or layer or intervening elements or layers may be present. In contrast, when an element is referred to as being “directly on” or “directly connected to” another element or layer, there are no intervening elements or layers present. Like reference numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “lower,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Example embodiments of the present invention are described herein with reference to cross-sectional illustrations that are schematic illustrations of idealized embodiments (and intermediate structures) of the present invention. As such, variations from the shapes of the illustrations as a result, for example, of manufacturing techniques and/or tolerances, are to be expected. Thus, example embodiments of the present invention should not be construed as limited to the particular shapes of regions illustrated herein but are to include deviations in shapes that result, for example, from manufacturing. The regions illustrated in the figures are schematic in nature and their shapes are not intended to illustrate the actual shape of a region of a device and are not intended to limit the scope of the present invention.

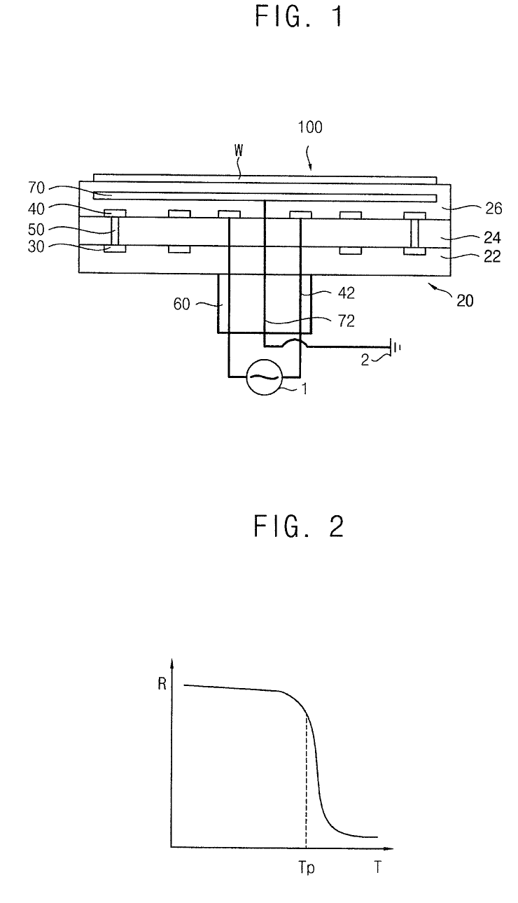

FIG. 1 is a schematic view illustrating a ceramic heater in accordance with an example embodiment of the present invention, and FIG. 2 is a graph illustrating the temperature and electrical resistance of a connecting member of the ceramic heater shown in FIG. 1.

Referring to FIGS. 1 and 2, a ceramic heater 100, in accordance with an example embodiment of the present invention, may include a plate 20, a first heating layer 30, a second heating layer 40 and a connecting member 50.

A substrate W may be placed on an upper surface of the plate 20. For example, the substrate W may be a silicon wafer that may be used for manufacturing semiconductor devices. Alternatively, the substrate W may be a thin-film transistor (TFT) substrate or a color filter (CF) substrate that may be used for manufacturing a flat panel display.

The plate 20 may include first, second and third ceramic layers 22, 24 and 26. Particularly, the first, second and third ceramic layers 22, 24 and 26 may be formed by a sintering process.

Though divided into the first, second and third ceramic layers 22, 24 and 26 as shown in FIG. 1, the plate 20 may be substantially formed in one piece by a sintering process.

The first heating layer 30 may be disposed within the plate 20. The second heating layer 40 may be disposed parallel to the first heating layer 30 within the plate 20. For example, the second heating layer 40 may be disposed over the first heating layer 30. Particularly, the first heating layer 30 may be disposed between the first and second ceramic layers 22 and 24, and the second heating layer 40 may be disposed between the second and third ceramic layers 24 and 26. The first and second heating layers 30 and 40 may include a heating wire capable of generating heat due to driving power.

Particularly, each of the first and second heating layers 30 and 40 may include a heating wire having a plate-like structure. For example, the heating wire may have a plate-like structure such as a spiral shape, a mesh shape, a horseshoe shape, a zigzag shape, and the like.

The second heating layer 40 may be entirely disposed between the second and third ceramic layers 24 and 26 to thereby correspond to the size of the plate 20, and the first heating layer 30 may be partially disposed between the first and second ceramic layers 22 and 24 to thereby correspond to a portion of the second heating layer 40.

As a result, a portion of the plate 20 may be additionally heated by the first heating layer 30. Alternatively, the first heating layer 30 may be configured to entirely correspond to the second heating layer 40 so as to entirely assist the first heating layer 30 in heating the plate 20 and the substrate W.

The second heating layer 40 may be electrically connected with an external power supply 1 by a power line 42 so that the driving power may be applied to the second heating layer 40 from the power supply 1. The first heating layer 30 may be connected with the second heating layer 40 by the connecting member 50 so that the driving power may be applied to the first heating layer 30 via the second heating layer 40 and the connecting member 50. That is, the connecting member 50 may connect the first heating layer 30 with the second heating layer 40 through the second ceramic layer 24.

The connecting member 50 may include a ceramic material having a negative temperature coefficient (NTC). For example, an NTC thermistor may be used as the connecting member 50.

A volume resistance (R) of the connecting member 50 may be generally evenly maintained when a temperature (T) of the connecting member 50 is lower than a target temperature (Tp), and may then be rapidly reduced when the temperature (T) of the connecting member 50 becomes higher than the target temperature (Tp) as shown in FIG. 2.

That is, the connecting member 50 may be an insulating material at a temperature lower than the target temperature (Tp) and may be a conductive material at a temperature higher than the target temperature (Tp). Then, the volume resistance (R) of the connecting member 50 may be generally evenly maintained after being rapidly reduced at the temperature higher than the target temperature (Tp).

As a result, when a temperature of the second heating layer 40 becomes higher than the target temperature (Tp), the driving power may be applied to the first heating layer 30 through the connecting member 50 so that the plate 20 may be heated by the first heating layer 30 as well as the second heating layer 40.

For example, the connecting member 50 may include a first metal oxide and a second metal oxide. Examples of a first metal that may be used for the first metal oxide may include aluminum (Al), magnesium (Mg), and the like. Examples of a second metal that may be used for the second metal oxide may include indium (In), tin (Sn), manganese (Mn), cobalt (Co), nickel (Ni), chromium (Cr), copper (Cu), and the like. These second metals may be used alone or in a combination thereof. For example, indium-tin (In—Sn) may be used as the second metal. The target temperature (Tp) may be adjusted by a mixing ratio of the first and second metal oxides.

When the target temperature (Tp) is lower than about 0.4 times a process temperature for processing the substrate W, a first time required for heating the substrate W to the process temperature by sequentially using the second heating layer 40 and the first heating layer 30 may be similar to a second time required for heating the substrate W to the process temperature by simultaneously using the first heating layer 30 and the second heating layer 40. Further, when the target temperature (Tp) is higher than about 0.6 times the process temperature, the first time may be remarkably increased in comparison with the second time because a time required to apply the driving power to the first heating layer 30 is increased.

Thus, it may be desirable that the target temperature (Tp) be in a range from about 0.4 to about 0.6 times the process temperature. Particularly, the target temperature (Tp) may be about 0.5 times the process temperature.

For example, when heating the substrate W to a process temperature of about 300° C. to about 1,000° C. so as to form a thin layer on the substrate W, the target temperature may be determined to be in a range from about 150° C. to about 500° C.

Alternatively, the connecting member 50 may include a mixture of materials having different electrical resistances. For example, the connecting member 50 may include at least two of metal oxides such as barium oxide (BaO), titanium oxide (TiO₂), lead oxide (PbO), zirconium oxide (ZrO₂), yttrium oxide (Y₂O₃), and the like. In such a case, the target temperature (Tp) may be adjusted by a mixing rate of the metal oxides.

Meanwhile, a portion of the plate 20 between the first and second heating layers 30 and 40, i.e., the second ceramic layer 24, may further include about 0.01 to about 1.0 percent by weight of magnesium oxide (MgO), titanium oxide (TiO₂) or a mixture of magnesium oxide (MgO) and titanium oxide (TiO₂) to thereby allow the second ceramic layer 24 to have electrically excellent insulating properties at the temperature higher than the target temperature (Tp).

As described above, after the plate 20 is heated to the temperature higher than the target temperature (Tp) by the second heating layer 40 connected with the power supply 1, the driving power may be applied to the first heating layer 30 through the connecting member 50. Thus, the driving power may be prevented from being applied to the first heating layer 30 early in the heat generation of the plate 20. As a result, the power consumption of the ceramic heater 100 may be reduced.

Meanwhile, the ceramic heater 100 may further include a supporter 60 to support a central portion of the plate 20. One power line 42 may pass through the supporter 60 to connect the second heating layer 40 with the power supply 1. Thus, an inner diameter of the supporter 60 may be reduced.

Further, the ceramic heater 100 may include an electrode 70 disposed within the plate 20. The electrode 70 may have a plate-like structure and may be disposed parallel to the first and second heating layers 30 and 40 within the plate 20. For example, the electrode 70 may be disposed within the third ceramic layer 26. The electrode 70 may be used as a ground electrode for forming a plasma when forming a thin layer on the substrate W or etching a thin layer formed on the substrate W using the plasma. In such a case, the electrode 70 may be connected with an external ground 2 by a ground line 72 passing through the supporter 60.

Though not shown in figures, the ceramic heater 100 may further include a second electrode (not shown) to generate an electrostatic force to thereby hold the substrate W which is placed on the plate 20. The second electrode may be disposed parallel to the electrode 70 within the third ceramic layer 26.

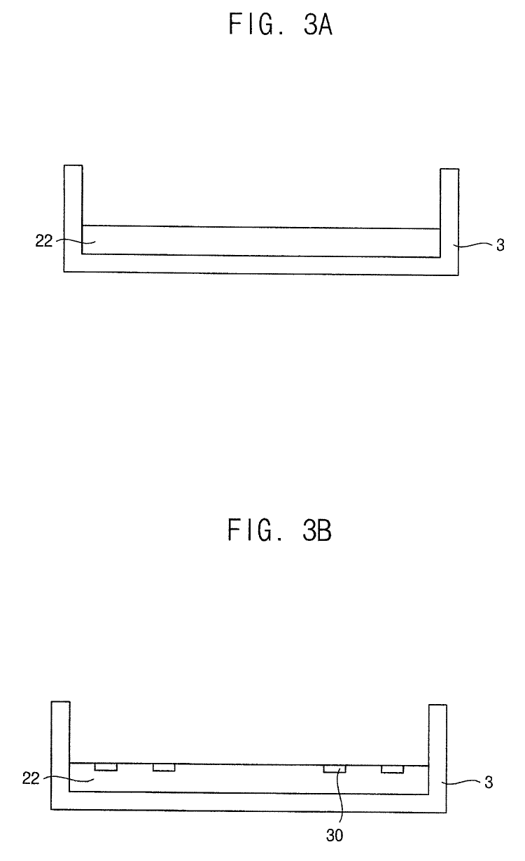

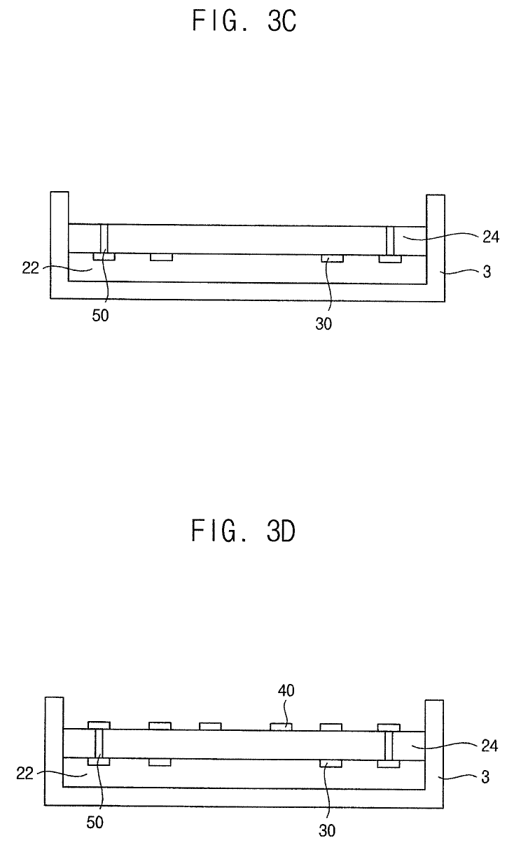

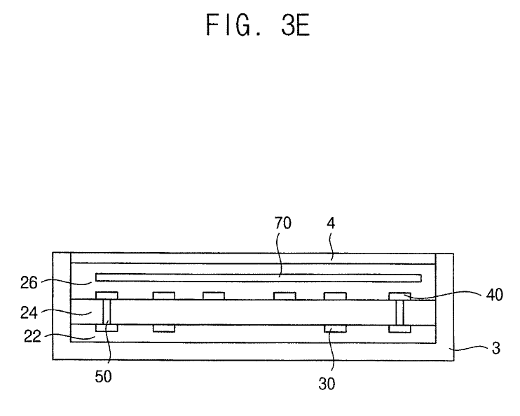

FIGS. 3A to 3E are schematic views illustrating a method of manufacturing the ceramic heater shown in FIG. 1.

Referring to FIG. 3A, a first ceramic powder having insulating properties such as aluminum nitride (AlN) may be supplied in a mold space of a lower mold 3 to thereby form a first ceramic layer 22. An upper surface of the first ceramic layer 22 may be planarized.

Referring to FIG. 3B, a first heating layer 30 may be disposed on the first ceramic layer 22. The first heating layer 30 may have a plate-like structure and may include a heating wire capable of generating heat due to the driving power.

Referring to FIG. 3C, a connecting member 50, which has insulating properties when under the target temperature and electrical conductivity when over the target temperature, may be connected onto the first heating layer 30. Here, the connecting member 50 may include a ceramic material having an NTC.

A second ceramic powder may be supplied onto the first ceramic layer 22 to thereby form a second ceramic layer 24. Here, an upper portion of the connecting member 50 may be exposed. The second ceramic powder may include aluminum nitride (AlN), and an upper surface of the second ceramic layer 24 may then be planarized.

Referring to FIG. 3D, a second heating layer 40 may be disposed on the second ceramic layer 24. The second heating layer 40 may be connected with the external power supply 1 and may further be connected with the exposed upper portion of the connecting member 50. The second heating layer 40 may have a plate-like structure and may include a heating wire capable of generating heat due to the driving power which is provided from the power supply 1.

When a temperature of the second heating layer 40 becomes higher than the target temperature (Tp) due to the driving power, the connecting member 50 may have the electrical conductivity. Thus, the driving power may be applied to the first heating layer 30 through the connecting member 50, and the first heating layer 30 may thus generate heat. That is, both of the first and second heating layers 30 and 40 may generate heat at the temperature higher than the target temperature (Tp).

Here, because the second ceramic layer 24 is brought into direct contact with the connecting member 50, the second ceramic powder may further include about 0.01 to about 1.0 percent by weight of magnesium oxide (MgO), titanium oxide (TiO₂) or a mixture of magnesium oxide (MgO) and titanium oxide (TiO₂) so that the second ceramic layer 24 may have good insulating properties at the temperature higher than the target temperature (Tp).

Referring to FIG. 3E, a third ceramic powder may be supplied onto the second ceramic layer 24 to thereby form a third ceramic layer 26. The third ceramic powder may include aluminum nitride (AlN), and an upper surface of the third ceramic layer 26 may be planarized.

Further, a ground electrode 70 may be buried in the third ceramic layer 26, which may be used to form a plasma for processing a substrate W.

An upper mold 4 may be coupled to an upper portion of the lower mold 3 in which the first, second and third ceramic layers 22, 24 and 26 are received. Then, a ceramic heater 100 may be completed by a sintering process. The first, second and third ceramic layers 22, 24 and 26 may be pressed by the upper mold 4 and may be heated to a sintering temperature during the sintering process.

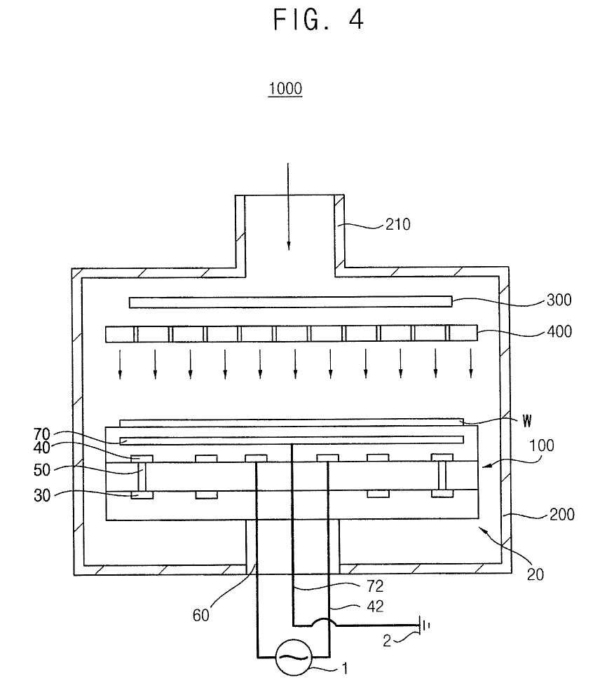

FIG. 4 is a schematic view illustrating an apparatus for forming a thin layer including the ceramic heater shown in FIG. 1.

Referring to FIG. 4, an apparatus 1000 for forming a thin layer, in accordance with an example embodiment of the present invention, may include a ceramic heater 100 as shown in FIG. 1, a process chamber 200 and a plasma electrode 300.

The process chamber 200 may include a gas inlet 210 through which a reactive gas is supplied thereinto. The reactive gas may include a source gas such as silane (SiH₄), nitrogen (N₂), ammonia (NH₃), and the like. Further, the reactive gas may further include an inert gas such as argon (Ar). The inert gas may be used as a carrier gas and may used to ignite a plasma in the process chamber 200.

The ceramic heater 100 may be disposed in the process chamber 200 to support and to heat a substrate W. For example, the substrate W may be placed on the ceramic heater 100 and may be heated by the ceramic heater 100 to a process temperature to form the thin layer on the substrate W.

The ceramic heater 100 may include a plate 20 including an insulating ceramic material, first and second heating layers 30 and 40 disposed parallel to each other within the plate 20, and a connecting member 50 to connect the first heating layer 30 with the second heating layer 40. Here, the second heating layer 40 may be connected with an external power supply 1 for providing driving power.

The connecting member 50 may include a ceramic material having an NTC so that the driving power may be sequentially applied to the second heating layer 40 and the first heating layer 30. For example, an NTC thermistor may be used as the connecting member 50.

The connecting member 50 may have a high volume resistance under a predetermined target temperature and a low volume resistance over the target temperature. That is, the plate 20 may be heated by the second heating layer 40 at a temperature lower than the target temperature and may then be heated by the first heating layer 30 as well as the second heating layer 40 because the driving power is applied to the first heating layer 30 through the connecting member 50 at the temperature higher than the target temperature.

Here, the target temperature may be about 0.4 to about 0.6 times the process temperature. Particularly, the target temperature may be about 0.5 times the process temperature. For example, when the process temperature is in a range from about 300° C. to about 1,000° C., the target temperature may be determined to be in a range from about 150° C. to about 500° C.

As described above, the first heating layer 30 may generate heat due to the driving power supplied through the connecting member 50 after the temperature of the second heating layer 40 becomes higher than the target temperature. Thus, the power required for heating the plate 20 and the substrate W to the process temperature may be reduced.

The plasma electrode 300 may be disposed opposite to the ceramic heater 100 in the process chamber 200. The plasma electrode 300 may be used to form the plasma from the reactive gas, and the thin layer may be formed on the substrate W by reaction between the plasma and the substrate W.

Though not shown in figures, the plasma electrode 300 may be electrically connected with an external radio frequency (RF) power source, and a radio frequency power may be applied to the plasma electrode 300 to form the plasma.

Meanwhile, the apparatus 1000 may further include a shower head 400 disposed between the ceramic heater 100 and the plasma electrode 300. The shower head 400 may be used to uniformly supply the reactive gas into the process chamber 200.

Though employed in the apparatus 1000 for forming the thin layer on the substrate W as described above, the ceramic heater 100 may be employed in an apparatus for etching the thin layer formed on the substrate W as well.

According to the example embodiments of the present invention as described above, a ceramic heater for heating a substrate may include first and second heating layers disposed parallel to each other within a plate and connected with each other by a connecting member. The connecting member may include an NTC ceramic material, and a power supply may be connected with the second heating layer. Thus, driving power may be applied to the first heating layer through the connecting member after a temperature of the second heating layer becomes higher than a target temperature. As a result, power consumption may be reduced early in the heat generation of the ceramic heater.

Although the example embodiments of the present invention have been described, it is understood that the present invention should not be limited to these example embodiments but various changes and modifications can be made by those skilled in the art within the spirit and scope of the present invention as hereinafter claimed.

What is claimed is:

1. A ceramic heater comprising:
a plate comprising a ceramic material and supporting a substrate;
a first heating layer disposed within the plate;
a second heating layer disposed parallel to the first heating layer within the plate and connected with a power supply for providing driving power; and
a connecting member disposed between the first heating layer and the second heating layer to electrically connect the first heating layer with the second heating layer at a temperature higher than a predetermined target temperature.

2. The ceramic heater of claim 1, wherein the connecting member comprises a ceramic material having a negative temperature coefficient.

3. The ceramic heater of claim 2, wherein the connecting member comprises a first metal oxide comprising at least one selected from the group consisting of aluminum (Al) and magnesium (Mg) and a second metal oxide comprising at least one selected from the group consisting of indium (In), tin (Sn), manganese (Mn), cobalt (Co), nickel (Ni), chromium (Cr) and copper (Cu).

4. The ceramic heater of claim 2, wherein the connecting member comprises at least two selected from the group consisting of barium oxide (BaO), titanium oxide (TiO₂), lead oxide (PbO), zirconium oxide (ZrO₂) and yttrium oxide (Y₂O₃).

5. The ceramic heater of claim 1, wherein the target temperature is about 0.4 to about 0.6 times a process temperature for processing the substrate.

6. The ceramic heater of claim 1, wherein the first heating layer corresponds to a portion of the second heating layer.

7. The ceramic heater of claim 1, wherein each of the first and second heating layers is a heating wire having a plate-like structure.

8. The ceramic heater of claim 1, wherein a portion of the plate between the first and second heating layers comprises about 0.01 to about 1.0 percent by weight of at least one of magnesium oxide (MgO) and titanium oxide (TiO₂).

9. The ceramic heater of claim 1, further comprising a supporter for supporting the plate, wherein the second heating layer is connected to the power supply by a power line passing through the supporter.

10. A method of manufacturing a ceramic heater comprising:
supplying a first ceramic powder in a mold space to form a first ceramic layer;
disposing a first heating layer on the first ceramic layer;
connecting a connecting member with the first heating layer, the connecting member having electrical conductivity at a temperature higher than a predetermined target temperature;
supplying a second ceramic powder onto the first ceramic layer to form a second ceramic layer so that an upper portion of the connecting member is exposed; and
disposing a second heating layer on the second ceramic layer so that the second heating layer is connected with the exposed upper portion of the connecting member;

11. The method of claim 10, wherein the second ceramic powder comprises about 0.01 to about 1.0 percent by weight of at least one of magnesium oxide (MgO) and titanium oxide (TiO₂).

12. The method of claim 10, further comprising supplying a third ceramic powder onto the second ceramic layer to form a third ceramic layer.

13. The method of claim 12, further comprising sintering the first, second and third ceramic layers supplied in the mold space.

14. An apparatus for forming a thin layer comprising:
a process chamber;
a ceramic heater disposed in the process chamber to support a substrate and to heat the substrate to a process temperature; and
a plasma electrode disposed opposite to the ceramic heater in the process chamber to form a plasma from a reactive gas supplied into the process chamber so as to form the thin layer on the substrate,
wherein the ceramic heater comprises:
a plate comprising a ceramic material and supporting the substrate;
a first heating layer disposed within the plate;
a second heating layer disposed parallel to the first heating layer within the plate and connected with a power supply for providing driving power; and
a connecting member disposed between the first heating layer and the second heating layer to electrically connect the first heating layer with the second heating layer at a temperature higher than a predetermined target temperature.

15. The apparatus of claim 14, wherein the target temperature is about 0.4 to about 0.6 times the process temperature.

16. The apparatus of claim 14, wherein the connecting member comprises a ceramic material having a negative temperature coefficient.
